(19) United States
(12) Patent Application Publication
(10) Pub. No.: US 2025/0048818 A1
(43) Pub. Date: Feb. 6, 2025

(54) MICRO LED AND MICRO LED DISPLAY PANEL

(71) Applicant: JADE BIRD DISPLAY (SHANGHAI) LIMITED, SHANGHAI (CN)

(72) Inventors: Zhichen GU, Shanghai (CN); Weisin TAN, Shanghai (CN)

(21) Appl. No.: 18/789,568

(22) Filed: Jul. 30, 2024

(30) Foreign Application Priority Data
Jul. 31, 2023 (WO) PCT/CN2023/110279

(51) Int. Cl. H01L 33/62; H01L 25/075; H01L 33/20; H01L 33/46

(52) U.S. Cl. CPC H01L 33/62; H01L 25/0753; H01L 33/20; H01L 33/46

(57) ABSTRACT

A micro LED includes a bonding layer; an N type semiconductor layer formed on the bonding layer; a light emitting layer formed on the N type semiconductor layer; a P type semiconductor layer formed on the light emitting layer; and a top conductive layer formed on the P type semiconductor layer. The bonding layer includes: a first metal bonding layer; a second metal bonding layer bonded with the N type semiconductor layer; and a transparent bonding layer formed between the first metal bonding layer and the second metal bonding layer; and the second metal bonding layer is semi-transparent.

### CROSS-REFERENCE TO RELATED APPLICATIONS

The present disclosure claims the benefits of priority to PCT Application No. PCT/CN2023/110279, filed on Jul. 31, 2023, which is incorporated herein by reference in its entirety.

### TECHNICAL FIELD

The present disclosure generally relates to micro LED manufacturing technology, and more particularly, to a micro LED and a micro LED display panel.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuit (IC) backplane. Each pixel of the micro LED display panel is formed by one or more micro LEDs. The micro LED display panel can be a mono-color or multi-color panel. In particular, for a multi-color LED panel, each pixel may further include multiple sub-pixels respectively formed by multiple micro LEDs, each of which corresponds to a different color. For example, three micro LEDs respectively corresponding to red, green, and blue colors may be superimposed to form one pixel. The different colors can be mixed to produce a broad array of colors.

Current micro LED technology faces several challenges, for example, improving light emission efficiency.

### SUMMARY OF THE DISCLOSURE

Embodiments of the present disclosure provide a micro LED. The micro LED includes a bonding layer; an N type semiconductor layer formed on the bonding layer; a light emitting layer formed on the N type semiconductor layer; a P type semiconductor layer formed on the light emitting layer; and a top conductive layer formed on the P type semiconductor layer. The bonding layer includes: a first metal bonding layer; a second metal bonding layer bonded with the N type semiconductor layer; and a transparent bonding layer formed between the first metal bonding layer and the second metal bonding layer. The second metal bonding layer is semi-transparent.

Embodiments of the present disclosure also provide a micro LED display panel. The micro LED display panel includes an integrated circuit (IC) backplane comprising a bottom pad array, the bottom pad array comprising a plurality of conductive bottom pads; and a micro LED array formed on the IC backplane, the micro LED array including a plurality of above-described micro LEDs; wherein one micro LED of the plurality of micro LEDs is electrically connected with one bottom pad of the plurality of conductive bottom pads.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing an exemplary micro LED, according to some embodiments of the present disclosure.

FIG. 2 illustrates a structural diagram showing further details of the exemplary micro LED illustrated in FIG. 1, according to some embodiments of the present disclosure.

FIG. 3 illustrates a structural diagram showing another exemplary micro LED, according to some embodiments of the present disclosure.

FIG. 4 illustrates a structural diagram showing a top view of an exemplary micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

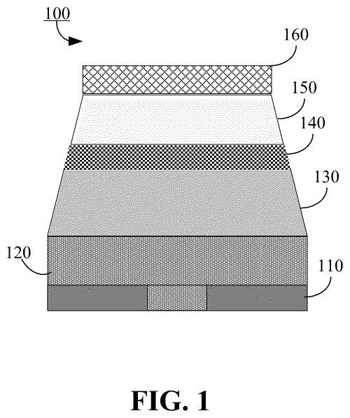

FIG. 1 illustrates a structural diagram showing an exemplary micro LED 100, according to some embodiments of the present disclosure. As shown in FIG. 1, micro LED 100 has a P-side up structure, and includes a bonding layer 120. An N type semiconductor layer 130 is provided on bonding layer 120, and bonding layer 120 is used to bond N type semiconductor layer 130 with an integrated circuit (IC) backplane 110. A light emitting layer 140 is formed on N type semiconductor layer 130. Light emitting layer 140 is configured to emit light. The light can be one of red light, green light, or blue light. A P type semiconductor layer 150 is formed on light emitting layer 140. A top conductive layer 160 is formed on P type semiconductor layer 150.

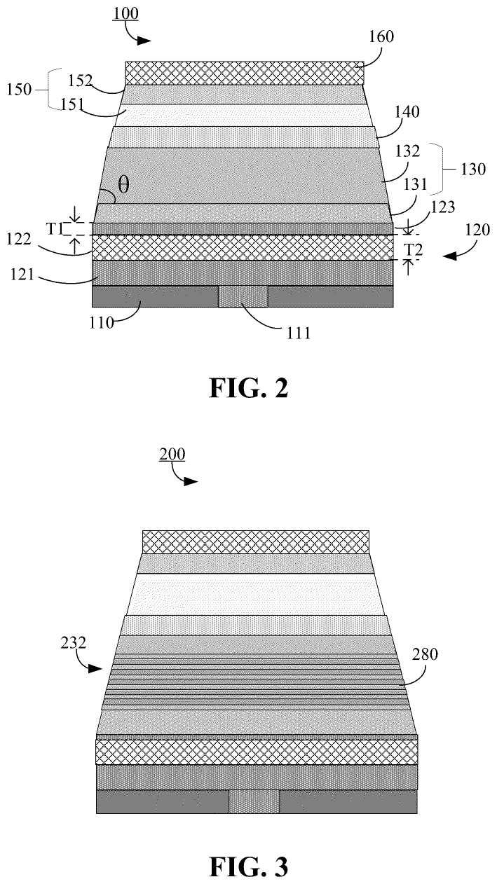

FIG. 2 illustrates a structural diagram showing further details of the exemplary micro LED 100 illustrated in FIG. 1, according to some embodiments of the present disclosure. As shown in FIG. 2, bonding layer 120 further includes a first metal bonding layer 121, a transparent bonding layer 122, and a second metal bonding layer 123 from bottom to top. N type semiconductor layer 130 is bonded with second metal bonding layer 123, first metal bonding layer 121 is bonded with IC backplane 110, and transparent bonding layer 122 is formed between first metal bonding layer 121 and second metal bonding layer 123. First metal bonding layer 121 and second metal bonding layer 123 are made of metal. In some embodiments, second metal bonding layer 123 is semi-transparent. Since second metal bonding layer 123 is semi-transparent, metal absorption is reduced, thereby improving light emission efficiency.

In some embodiments, a material of second metal bonding layer 123 is AuGe, which can improve an ohmic contact with N type semiconductor layer 130.

A thickness T1 of second metal bonding layer 123 is less than a thickness T2 of transparent bonding layer 122. In some embodiments the thickness T1 of do second metal bonding layer 123 is less than one hundredth ( 1/100) of the thickness of transparent bonding layer 122. In some embodiments, the thickness T1 of second metal bonding layer 123 is greater than one three-hundredth ( 1/300) of the thickness T2 of transparent bonding layer 122. In this example, the thickness T1 of second metal bonding layer 123 is from 1/300 to 1/100 of the thickness T2 of transparent bonding layer 122. In some embodiments, the thickness T2 of transparent bonding layer 122 can be in a range of 30 nm to 300 nm.

Since second metal bonding layer 123 is quite thin, the ohmic contact is further improved and the light emission efficiency is further increased.

In some embodiments, transparent bonding layer 122 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, or the like. IC backplane 110 includes a bottom pad 111 electrically connected to first metal bonding layer 121.

In some embodiments, thickness T2 of transparent bonding layer 122 is one fourth (¼) of a wavelength of light emitted by light emitting layer 140, that is,

$$T 2 = \frac{1}{4} λ ,$$

where λ is a wavelength of the light emitted by light emitting layer 140. For example, in some embodiments, when light emitted by light emitting layer 140 is red light, a wavelength of the red light is from 620 nm to 650 nm. When light emitted by light emitting layer 140 is green light, a wavelength of the green light is from 510 nm to 540 nm. When light emitted by light emitting layer 140 is blue light, a wavelength of the blue light is from 440 nm to 470 nm.

Since the thickness T2 of transparent bonding layer 122 is equal to one fourth of a wavelength of the light emitted by light emitting layer 140, metal absorption of first metal bonding layer 121 can be reduced and a reflectivity of bonding layer 120 is increased, thereby improving the light emission efficiency.

In some embodiments, light emitting layer 140 includes at least one quantum well layer. A thickness of the quantum well layer is from 20 nm to 40 nm, for example, 30 nm. In some embodiments, a material of the quantum well layer is GaInP/(AlₓGa₁₋ₓ)_{y}In_{1-y}P, where a range of x is from 0.5 to 0.9, and a range of y is from 0.3 to 0.5. For example, x is 0.8, and y is 0.5. In some embodiments, a relationship between x and y is that x is 1 to 2 times y. In some embodiments, light emitting layer 140 is a multiple quantum well (MQW).

In some embodiments, N type semiconductor layer 130 further includes a doped N type contact layer 131 and an N type cladding layer 132. Doped N type contact layer 131 is configured to bond with bonding layer 120, and N type cladding layer 132 is formed on doped N type contact layer 131. A material of N type cladding layer 132 is AlₓIn₁₋ₓP, where a range of x is from 0.1 to 0.5, for example, x is 0.5. Further, in such embodiments, a thickness of N type cladding layer 132 is not greater than 350 nm, for example, the thickness of N type cladding layer 132 is 320 nm. A doping concentration of N type cladding layer 132 is from 5e¹⁷ cm⁻³ to 1e¹⁸ cm⁻³.

In some embodiments, N type semiconductor layer 130 further includes a doped N type contact layer 131, and N type cladding layer 132 formed on doped N type contact layer 131. Doped N type contact layer 131 is configured to bond with bonding layer 120. A material of doped N type contact layer 131 is GaAs. In some embodiments, a thickness of doped N type contact layer 131 is from 10 nm to 30 nm. In some embodiments, a doping concentration of doped N type contact layer 131 is from 2e¹⁸ cm⁻³ to 1e¹⁹ cm⁻³.

In some embodiments, N type semiconductor layer 130 further includes an N type spacer layer (not shown) formed on N type cladding layer 132. A material of the N type spacer layer is (AlₓGa₁₋ₓ)_{y}In_{1-y}P, where a range of x is from 0.5 to 0.9, and a range of y is from 0.1 to 0.5. For example, x is 0.8, and y is 0.5. In some embodiments, a relationship between x and y is that x is 1 to 2 times y. A thickness of the N type spacer layer is from 50 nm to 75 nm, for example, 65 nm.

In some embodiments, P type semiconductor layer 150 includes a P type cladding layer 151 and a doped P type contact layer 152. P type cladding layer 151 is formed on light emitting layer 140, and doped P type contact layer 152 is formed on P type cladding layer 151.

In some embodiments, a material of P type cladding layer 151 is AlₓIn₁₋ₓP, where x is from 0.3 to 0.5, for example, x is 0.5. In such embodiments, a thickness of P type cladding layer 151 is not greater than 380 nm, for example, the thickness of P type cladding layer 151 is 360 nm.

In some embodiments, a material of doped P type contact layer 152 is GaAs. A thickness of doped P type contact layer 152 is from 10 nm to 30 nm, for example, 20 nm.

In some embodiments, P type semiconductor layer 150 further includes a P type spacer layer (not shown) formed under P type cladding layer 151, a first doped P type transition layer (not shown) formed on P type cladding layer 151, and a second doped P type transition layer (not shown) formed on the first doped P type transition layer. In some embodiments, a material of the P type spacer layer is (AlₓGa₁₋ₓ)_{y}In_{1-y}P, where a range of x is from 0.5 to 0.9, and a range of y is from 0.3 to 0.5. For example, x is 0.8, and y is 0.5. In some embodiments, a relationship between x and y is that x is 1 to 2 times y. In some embodiments, a thickness of the P type spacer layer is from 50 nm to 70 nm, for example, 65 nm.

In some embodiments, a material of the first doped P type transition layer is (AlₓGa₁₋ₓ)_{y}In_{1-y}P, where a range of x is from 0.1 to 0.3, and a range of y is from 0.3 to 0.5. For example, x is 0.17 and y is 0.5. In some embodiments, a relationship between x and y is that y is 1 to 5 times x. In some embodiments, a thickness of the first doped P type transition layer is from 20 nm to 40 nm, for example, 30 nm.

In some embodiments, a material of the second doped P type transition layer is AlₓGa₁₋ₓAs, where a range of x is from 0.5 to 0.9, for example, x is 0.6. In some embodiments, a thickness of the second doped P type transition layer is from 10 nm to 30 nm, for example, 20 nm.

In some embodiments, a doping concentration of the second doped P type transition layer is greater than a doping concentration of the first doped P type transition layer. A doping concentration of doped P type contact layer 152 is 1 to 10 times the doping concentration of second doped P type transition layer.

In some embodiments, the doping concentration of doped P type contact layer 152 is greater than the doping concentration of the second doped P type transition layer. Further, in some embodiments, the doping concentration of the second doped P type transition layer is 2 to 4 times a doping concentration of the first doped P type transition layer.

For example, the doping concentration of the first doped P type transition layer is greater than 1e¹⁸ cm⁻³, the doping concentration of the second doped P type transition layer is in a range of 2e¹⁸ cm⁻³ to 4e¹⁸ cm⁻³, and the doping concentration of doped P type contact layer 152 is greater than 5e¹⁸ cm⁻³.

Still referring to FIG. 2, a sidewall of P type semiconductor layer 150, light emitting layer 140, and N type semiconductor layer 130 is inclined. That is, sidewalls of P type semiconductor layer 150, light emitting layer 140, and N type semiconductor layer 130 are along a straight line, and an inclined angle θ is formed between the straight line and a bottom of N type semiconductor layer 130. In some embodiments, the inclined angle θ of the sidewall is from 55 degrees to 65 degrees. A top surface area of P type semiconductor layer 150 is smaller than a top surface area of N type semiconductor layer 130. In some embodiments, a cross section of a top surface of micro LED 100 is a circular, and a diameter of P type semiconductor layer 150 is smaller than a diameter of N type semiconductor layer 130. Accordingly, micro LED 100 has a tapered mesa structure.

In some embodiments, the inclined angle θ of the sidewall is greater than 85 degrees, for example, between 85 degrees to 90 degrees. Therefore, a micro LED may have a vertical mesa structure, which can increase beam angle performance. Also, light emitting area can be larger, thereby increasing the light emission efficiency.

FIG. 3 illustrates a structural diagram showing an exemplary micro LED 200, according to some embodiments of the present disclosure. As shown in FIG. 3, N type cladding layer 232 includes a distributed Bragg reflection (DBR) structure 280. DBR structure 280 may be at a part of N type cladding layer 232, for example, at a bottom of N type cladding layer 232. In some embodiments, DBR structure 280 may be at a top of N type cladding layer 232. In some embodiments, all of N type cladding layer 232 may be DBR structure 280. In some embodiments, DBR structure 280 includes a plurality of first layers and a plurality of second layers. The plurality of first layers and the plurality of second layers being alternately layered. In some embodiments, materials of the plurality of first layers and the plurality of second layers are AlInP and AlGaInP, respectively. In some embodiments, materials of the plurality of first layers and the plurality of second layers are AlGaAs and AlAs, respectively. Other structures of micro LED 200 may refer to those described above with reference to FIG. 2, which will not be repeated herein.

With DBR structure 280 provided in micro LED 200, the reflectivity is increased and bottom metal absorption is reduced, thereby increasing the light emission efficiency.

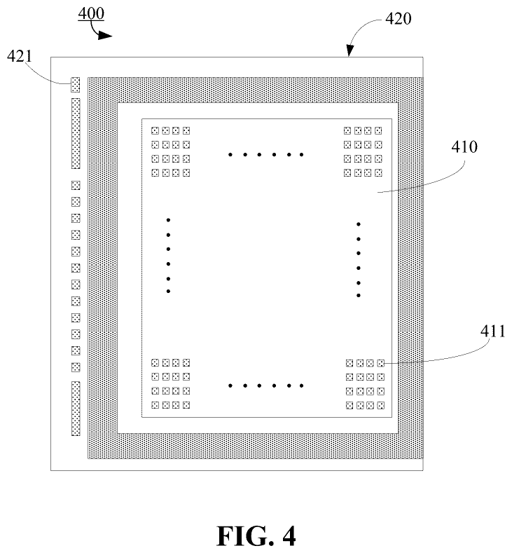

FIG. 4 illustrates a structural diagram showing a top view of a micro LED display panel 400, according to some embodiments of the present disclosure. Referring to FIG. 4, micro LED display panel 400 includes a micro LED array 410 and an IC (integrated circuit) backplane 420. Micro LED array 410 is located on IC backplane 420 to form an image display area of micro LED display panel 400. The rest of the area on IC backplane 420 not covered by micro LED array 410 is formed as a non-functional area. IC backplane 420 is formed at the back surface of micro LED array 410 with a part extending outside of, i.e., not covered by, micro LED array 410. Micro LED array 410 includes a plurality of micro LEDs 411 provided in an array. IC backplane 420 is configured to control the plurality of micro LEDs 411. IC backplane 420 may include a bottom pad array (not shown) corresponding to micro LED array 410. The bottom pad array includes a plurality of conductive bottom pads (for example, bottom pad 111 in FIG. 2), and one bottom pad corresponds to one micro LED 411. One micro LED of the plurality of micro LEDs is electrically connected with one bottom pad of the plurality of conductive bottom pads.

In some embodiments, a top conductive layer (for example, top conductive layer 160 in FIG. 1) of the micro LED is interconnected with each of the plurality of micro LEDs. That is, the top conductive layer is continuously formed on a top of micro LED array 410, and connected with every micro LED 411.

In some embodiments, IC backplane 420 further includes a top connected pad 421. The top conductive layer is connected with top connected pad 421, and further may connect to an external circuit.

Each micro LED herein (e.g., micro LED 100 or 200) has a very small volume. The micro LED can be applied in a micro LED display panel. The light emitting area of the micro LED display panel, e.g., micro LED display panel 400, is very small, such as 1 mm×1 mm, 3 mm×5 mm, etc. In some embodiments, the light emitting area is the area of the micro LED array in the micro LED display panel. The micro LED display panel includes one or more micro LEDs that form a pixel array in which the micro LEDs are pixels, such as a 1600×1200, 680×480, or 1920×1080-pixel array. The diameter of each micro LED is in the range of about 200 nm to 2 μm. An IC backplane, e.g., IC backplane 420, is formed at the back surface of micro LED array 410 and is electrically connected with micro LED array 410. The IC backplane acquires signals such as image data from outside via signal lines to control corresponding micro LEDs to emit light or not.

It is understood by those skilled in the art that the micro LED display panel is not limited by the structure described above, and may include greater or fewer components than those illustrated, or some components may be combined, or a different component may be utilized.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED comprising:
a bonding layer;
an N type semiconductor layer formed on the bonding layer;
a light emitting layer formed on the N type semiconductor layer;
a P type semiconductor layer formed on the light emitting layer; and
a top conductive layer formed on the P type semiconductor layer;
wherein the bonding layer comprises:
a first metal bonding layer;
a second metal bonding layer bonded with the N type semiconductor layer; and
a transparent bonding layer formed between the first metal bonding layer and the second metal bonding layer; wherein the second metal bonding layer is semi-transparent.

2. The micro LED according to claim 1, wherein material of the second metal bonding layer is AuGe.

3. The micro LED according to claim 1, wherein a thickness of the second metal bonding layer is less than a thickness of the transparent bonding layer.

4. The micro LED according to claim 3, wherein the thickness of the second metal bonding layer is less than one hundredth of the thickness of the transparent bonding layer.

5. The micro LED according to claim 4, wherein the thickness of the second metal bonding layer is greater than one three-hundredth of the thickness of the transparent bonding layer.

6. The micro LED according to claim 1, wherein an inclined angle of a sidewall of the P type semiconductor layer, the light emitting layer, and the N type semiconductor layer is greater than 85 degrees.

7. The micro LED according to claim 1, wherein a thickness of the transparent bonding layer is one fourth of a wavelength of light emitted by the light emitting layer.

8. The micro LED according to claim 1, wherein the N type semiconductor layer further comprises:
a doped N type contact layer formed on the bonding layer; and
an N type cladding layer formed on the doped N type contact layer, wherein the N type cladding layer comprises a distributed Bragg reflection (DBR) structure.

9. The micro LED according to claim 8, wherein the DBR structure comprises a plurality of first layers and a plurality of second layers, the plurality of first layers and the plurality of second layers being alternately layered.

10. The micro LED according to claim 9, wherein materials of the plurality of first layers and the plurality of second layers are AlInP and AlGaInP, respectively, or AlGaAs and AlAs, respectively.

11. A micro LED display panel comprises:
an integrated circuit (IC) backplane comprising a bottom pad array, the bottom pad array comprising a plurality of conductive bottom pads; and
a micro LED array formed on the IC backplane, the micro LED array comprising a plurality of micro LEDs;
wherein one micro LED of the plurality of micro LEDs is electrically connected with one bottom pad of the plurality of conductive bottom pads; and the micro LED comprises:
a bonding layer;
an N type semiconductor layer formed on the bonding layer;
a light emitting layer formed on the N type semiconductor layer;
a P type semiconductor layer formed on the light emitting layer; and
a top conductive layer formed on the P type semiconductor layer;
wherein the bonding layer comprises:
a first metal bonding layer;
a second metal bonding layer bonded with the N type semiconductor layer; and
a transparent bonding layer formed between the first metal bonding layer and the second metal bonding layer; wherein the second metal bonding layer is semi-transparent.

12. The micro LED display panel according to claim 11, wherein respective top conductive layers of the plurality of micro LEDs are interconnected.

13. The micro LED display panel according to claim 12, wherein the IC backplane further comprises a top connected pad, and the respective top conductive layers are connected with the top connected pad of the IC backplane.
